(19) United States
(12) Patent Application Publication
(10) Pub. No.: US 2022/0173261 A1
(43) Pub. Date: Jun. 2, 2022

(54) PHOTOVOLTAIC CELL AND STRING AND ASSOCIATED METHODS

(71) Applicant: COMMISSARIAT À L'ÉNERGIE ATOMIQUE ET AUX ÉNERGIES ALTERNATIVES, PARIS (FR)

(72) Inventor: Armand BETTINELLI, GRENOBLE CEDEX 09 (FR)

(21) Appl. No.: 17/599,909

(22) PCT Filed: Mar. 31, 2020
(86) PCT No.: PCT/EP2020/059140

§ 371 Date: Sep. 29, 2021

(30) Foreign Application Priority Data
Apr. 1, 2019 (FR) FR1903460

(51) Int. Cl. H01L 31/0224; H01L 31/05; H01L 31/18

(52) U.S. Cl. CPC H01L 31/022433; H01L 31/1876; H01L 31/0508

(57) ABSTRACT

A photovoltaic cell includes a front face intended to be exposed to an incident radiation and a rear face opposite to the front face, the front face having a plurality of electrodes parallel with each other and forming collection fingers; an interconnection conductive track of width greater than the width of the collection fingers, extending parallel to an edge of the photovoltaic cell at less than 2 mm from the edge of the photovoltaic cell, the collection fingers being oriented with respect to the interconnection conductive track by an angle comprised between −65° and 65°; and wherein a part at least of the collection fingers are interconnected by connection elements in the form of wires or ribbons arranged on the front face.

### TECHNICAL FIELD

The present invention relates to a photovoltaic cell, to a string of photovoltaic cells, wherein the photovoltaic cells partially overlap, and to the respective manufacturing methods thereof.

### PRIOR ART

A photovoltaic module comprises a multitude of identical photovoltaic cells connected in series and/or in parallel in order to provide at the output the voltage and/or the current required to supply electrical devices. The most common module format employs 60 square (or “pseudo-square”) cells, of 156 mm sides, distributed in six “strings” of ten cells connected in series. The six strings of photovoltaic cells are also connected in series.

The photogenerated charge carriers, which contribute to the electric current of the photovoltaic cell, are collected by means of a network of electrodes deposited on the front face of the cell. These electrodes, also called collection fingers, are narrow (<100 μm). They are generally formed by screen printing of a paste containing silver. The rear face of the cell is either covered with another network of electrodes (case of bifacial cells), or with a solid metal layer, for example made of aluminium (case of monofacial cells). The electric current next circulates from one cell to the other of the string by interconnections.

Two major techniques for interconnecting the photovoltaic cells of a string may be distinguished today: ribbon shaped interconnections and electrical wire shaped interconnections. These two techniques are represented by FIGS. 1 and 2 respectively.

In FIG. 1, the interconnections between the cells 10 are constituted of copper ribbons 11 covered with a fusible alloy, typically an alloy of tin and lead or an alloy of tin and silver. These ribbons 11 of rectangular section are soldered on conductive tracks called “busbars” and formed at the same time as the collection fingers 12 by screen printing. The busbars electrically connect the collection fingers 12 and are oriented perpendicularly to the collection fingers 12.

A 156 mm×156 mm cell generally comprises three ribbons of 1.5 mm width or four ribbons of 1.2 mm width, these ribbons having a thickness of the order of 0.2 mm. Each ribbon 11 connects the front face of a cell 10 to the rear face of the following cell in the string (not represented in FIG. 1). The connection in series of the photovoltaic cells 10 by means of ribbons 11 takes place in an entirely automated manner, in an equipment called a “stringer”.

Several equipment manufacturers henceforth propose replacing copper ribbons by electrical wires of smaller section. For example, the “Multi-Busbar” technology developed by the “Schmid” Company and described in the article [“Multi-busbar solar cells and modules: high efficiencies and low silver consumption”, S. Braun et al., Energy Procedia, vol. 38, pp. 334-339, 2013] multiplies the number of busbars deposited on the cell, going from three to fifteen busbars, and solders to each busbar a wire of 200 μm diameter. This technology is represented schematically in FIG. 2. The wires 20 are constituted of copper and covered with a thin layer of a tin-lead-based or tin-silver-based alloy of which the melting point lies above 170° C. The busbars have a discontinuous shape. They are composed of metallisation pads 21, of around 500 μm×700 μm, aligned on the collection fingers 12. The metallisation pads 21 and the collection fingers 12 are generally produced by screen printing of a silver paste. The soldering of the wires 20 on the pads 21 takes place immediately after having placed the wires on the pads, in the same equipment, while heating these elements to a temperature of the order of 200° C. Thus, the alloy covering the copper wires is melted.

The “SmartWire” technology developed by the “Meyer Burger” company and described in the article [“Smart Wire Connection Technology”, T. Söderström et al., Proceedings of the 28th European Photovoltaics Solar Energy Conference, pp. 495-499, 2013] consists in depositing a sheet of 18 to 36 wires of 200 μm or 300 μm diameter directly on the collection fingers. In other words, the photovoltaic cells are exempt of busbars. The wires are held by a support film made of polyethylene terephthalate (PET), which is bonded onto each face of the cells. The wires have a copper core and an outer coating formed of an indium-based alloy. This alloy has a melting temperature less than 150° C., which makes it possible to carry out the electrical connection between the wires and the collection fingers, not during the step of interconnection of the cells (by local heating to 200° C.), but during the step of lamination of the photovoltaic modules (which takes place at lower temperature, generally around 150-160° C.).

Electric wire shaped interconnections make it possible to reduce the length of the collection fingers with respect to the three busbars configuration (FIG. 1), because the number of wires is greater than the number of ribbons. This increase in the number of interconnections does not necessarily have an impact on the shading of the photovoltaic cell on account of the smaller size of the wires. On the other hand, it makes it possible to reduce considerably the amount of silver used to print the collection fingers. Indeed, the collection fingers being shorter, it is possible either to reduce the width of the fingers or to use a paste less rich in silver (and thus less conductive) for an equivalent series resistance. Further, thanks to their circular section, electric wires have an effective shading on the photovoltaic cell equal to 70% only of their diameter, compared to 100% of the width of ribbons. Thus, for a set of interconnections having a same transversal section, the shading level on cells interconnected by wires is lower than that on cells interconnected by ribbons.

The collection fingers are at the origin of resistive losses which deteriorate the fill factor (FF) of the photovoltaic cell, and thus its efficiency. As a reminder, the fill factor FF represents the “difference” of the real I-V characteristic of the cell with respect to an ideal rectangular characteristic. Its expression is the following:

$$FF = \frac{{P}_{opt}}{{I}_{CC} \times {V}_{CO}} \qquad [ Math 1 ]$$

where Pₒₚₜ is the power supplied by the cell at the optimal operating point of the real I-V characteristic, I_{CC} is the short-circuit current and V_{CO} is the open circuit voltage. The efficiency n of the cell is linked to the fill factor FF by the following relationship:

$$η = \frac{{V}_{CO} \cdot {I}_{CC} \cdot FF}{{P}_{i}} \qquad [ Math 2 ]$$

where Pᵢ is the power of the incident solar radiation.

To these resistive losses at the level of the cell, it is necessary to add the resistive losses at the level of the module, i.e. in the interconnections. The resistive losses in the interconnections are proportional to the square of the electric current I generated by the module and to the series resistance R_{S} of the interconnections, which depends notably on the section of copper used.

Furthermore, a technique of interconnecting photovoltaic cells called “shingle” exists which does not use ribbons or electric wires. The “shingle” interconnection technique is for example described in the article [“Materials challenge for shingled cells interconnection”, G. Beaucame, Energy Procedia 98, pp. 115-124, 2016].

FIGS. 3A and 3B show respectively the front face 30a and the rear face 30b of a photovoltaic cell 30 suitable for the “shingle” interconnection technique. The photovoltaic cell 30 is of rectangular shape. Its front face 30a has an interconnection conductive track or busbar 31a and a plurality of collection fingers 12 oriented perpendicularly to the busbar 31a. The busbar 31a extends parallel to the largest side of the photovoltaic cell 30 and electrically connects the collection fingers 12. As illustrated by FIG. 1B, the rear face 30b of the cell may have a configuration of electrodes similar to that of the front face 30a (case of bifacial cells), i.e. comprising a busbar 31b and collection fingers 12, with the difference that the busbar 31b is situated along the opposite side of the photovoltaic cell 30. Alternatively, the rear face 30b of the cell may be completely metallised (case of monofacial cells) and only comprise the busbar 31b.

FIGS. 4A and 4B represent, respectively, in top view and in transversal section, a “shingled” cell string 40 manufactured by interconnecting several photovoltaic cells 30, such as illustrated by FIGS. 3A and 3B. The photovoltaic cells 30 of the string slightly overlap, like tiles or shingles on a roof. A portion of the front face 30a of each cell 30, except for the final cell of the string, is overlapped by the following cell in the string. The busbar 31a of the cell is situated in this so-called “overlap” portion. It is interconnected with the busbar 31b situated on the rear face 30b of the following cell 30, for example by means of an electrically conductive adhesive (ECA) 35.

In the “shingled” cell string 40, there is no space between the cells as in conventional cell strings, formed by means of ribbons or wires. Shading is moreover minimal, because there are no interconnection elements in the form of wire or ribbon transferred onto the front face 30a of the cells and the busbar 31a on the front face is overlapped by an active surface of another cell. A photovoltaic module or panel constructed from such strings will thus have a maximum active surface to total surface ratio, making it possible to obtain very high panel efficiency.

The “shingle” interconnection technique suffers however from a major drawback: that of the cost of manufacturing a string of photovoltaic cells. Indeed, in the “shingled” cell string 40, the electric current produced by the cells flows through the entire length of the collection fingers 12. To limit resistive losses in the collection fingers 12, these are thus wider and thicker than in conventional cell strings. The amount of silver used to form the collection fingers 12 is then very important, which significantly increases the manufacturing cost of a cell and thus of the cell string. This cost drawback is particularly critical in the case of heterojunction cells which are metallised with more resistive silver pastes than those used for homojunction cells (because having to be baked at low temperature, around 200° C.). Another drawback of using wide collection fingers is the decrease in current produced by each cell, wide collection fingers causing more important shading.

### SUMMARY OF THE INVENTION

There thus exists a need to manufacture at lower costa “shingled” string of photovoltaic cells without decreasing the electrical performances of the string.

According to a first aspect of the invention, this need tends to be satisfied by providing a photovoltaic cell comprising a front face intended to be exposed to an incident radiation and a rear face opposite to the front face, the front face having:
a plurality of electrodes parallel with each other and called “collection fingers”;
an interconnection conductive track of width greater than the width of the collection fingers, extending parallel to an edge of the photovoltaic cell at less than 2 mm from said edge of the photovoltaic cell, preferably at less than 1 mm from said edge of the photovoltaic cell, the collection fingers being oriented with respect to the interconnection conductive track by an angle comprised between −65° and 65°;
   and wherein a part at least of the collection fingers are interconnected by connection elements in the form of wires or ribbons arranged on the front face.

By orienting the collection fingers with respect to the interconnection conductive track by an angle comprised between −65° and 65°, it is possible to interconnect all or part of the collection fingers together by means of connection elements transferred onto the front face of the cell. The electric current is then in part conveyed by the connection elements, for example in the form of ribbons or wires, and no longer exclusively by the collection fingers. The amount of silver used to form the collection fingers may then be decreased without this having a significant impact on the series resistance of the cell.

The photovoltaic cell according to the first aspect of the invention thus makes it possible to obtain at lower cost a “shingled” cell string having high performances, notably in terms of current generated. A “shingle” cell string designates a string of photovoltaic cells (obtained by the “shingle” interconnection technique) wherein the photovoltaic cells overlap, front face against rear face, to be interconnected in series (the photovoltaic cells of the string are arranged like the tiles of a roof).

The photovoltaic cell according to the first aspect of the invention may also have one or more of the characteristics below, considered individually or according to all technically possible combinations thereof.

The width of the interconnection conductive track is advantageously comprised between 70 μm and 700 μm.

Preferably, the front and rear faces are of rectangular shape and have a length to width ratio comprised between 2 and 10, preferably equal to a natural integer comprised between 2 and 10.

The connection elements are preferably oriented perpendicularly to the interconnection conductive track.

The collection fingers are preferably oriented parallel to the interconnection conductive track.

Preferably, at least one of the interconnected collection fingers is electrically connected to the interconnection conductive track.

In an embodiment, the photovoltaic cell further comprises connecting conductors electrically connecting said at least one of the interconnected collection fingers to the interconnection conductive track.

In an embodiment, the photovoltaic cell further comprises first connecting conductors electrically connecting the interconnection conductive track to the collection finger the closest to the interconnection conductive track.

In an embodiment, the photovoltaic cell further comprises second connecting conductors electrically connecting together the two collection fingers the furthest away from the interconnection conductive track.

In an embodiment, the photovoltaic cell further comprises third connecting conductors electrically connecting together the two collection fingers the closest to the interconnection conductive track.

In an embodiment, the photovoltaic cell further comprises a plurality of first solder pads aligned on the collection fingers and forming, perpendicularly to the collection fingers, a plurality of discontinuous connection tracks.

According to a development of this embodiment, the connection elements are fixed to the collection fingers through discontinuous connection tracks.

According to another development, the photovoltaic cell further comprises a plurality of second solder pads aligned on the interconnection conductive track, in the extension of the discontinuous connection tracks, the connection elements being further fixed to the interconnection conductive track through second solder pads.

In an embodiment, the rear face of the photovoltaic cell has:
a plurality of electrodes parallel with each other and called “collection fingers”;
an interconnection conductive track of width greater than the width of the collection fingers of the rear face, extending parallel to an edge of the photovoltaic cell at less than 2 mm from said edge of the photovoltaic cell, the collection fingers of the rear face being oriented with respect to the interconnection conductive track of the rear face by an angle comprised between −65° and 65°;
   and wherein a part at least of the collection fingers of the rear face are interconnected by additional connection elements in the form of wires or ribbons arranged on the rear face.

A second aspect of the invention relates to a photovoltaic string comprising first and second photovoltaic cells according to the first aspect of the invention, the second photovoltaic cell being interconnected with the first photovoltaic cell by overlapping with the rear face of the second photovoltaic cell a portion of the front face of the first cell wherein is situated the interconnection conductive track.

The photovoltaic string according to the second aspect of the invention may also have one or more of the characteristics below, considered individually or according to all technically possible combinations thereof.

According to a development of this embodiment, the connection elements are electric wires and the electric wires are integral with a support film arranged against the front faces of the first and second photovoltaic cells.

In an alternative embodiment, the connection elements extend up to the interconnection conductive track.

A third aspect of the invention relates to a method for manufacturing a photovoltaic cell. This method comprises the following steps:
forming on a face of a substrate a plurality of electrodes parallel with each other, called “collection fingers”, and an interconnection conductive track of width greater than the width of the collection fingers, the interconnection conductive track extending parallel to an edge of the substrate at less than 2 mm from said edge of the substrate, preferably at less than 1 mm from said edge of the substrate, and the collection fingers being oriented with respect to the interconnection conductive track by an angle comprised between −65° and 65°;
interconnecting a part at least of the collection fingers by connection elements in the form of wires or ribbons deposited on the face of the substrate.

The collection fingers and the interconnection conductive track are preferably formed by screen printing, for example of a paste containing silver.

A fourth aspect of the invention relates to a method for manufacturing a photovoltaic string. This method comprises the following steps:
providing first and second photovoltaic cells each comprising a front face intended to be exposed to an incident radiation and a rear face opposite to the front face, the front face having:
   a plurality of electrodes parallel with each other and called “collection fingers”;
   an interconnection conductive track of width greater than the width of the collection fingers, extending parallel to an edge of the photovoltaic cell at less than 2 mm from said edge of the photovoltaic cell, the collection fingers being oriented with respect to the interconnection conductive track by an angle comprised between −65° and 65°;
interconnecting in each of the first and second photovoltaic cells a part at least of the collection fingers by connection elements in the form of wires or ribbons deposited on the front face;
interconnecting the second photovoltaic cell with the first photovoltaic cell by overlapping a portion of the front face of the first photovoltaic cell wherein is situated the interconnection conductive track.

The method for manufacturing a photovoltaic string according to the fourth aspect of the invention may also have one or more of the characteristics below, considered individually or according to all technically possible combinations thereof.

In an embodiment, the connection elements are deposited on the front face of the first and second photovoltaic cells after the step of interconnection of the first and second photovoltaic cells.

According to a development of this embodiment, the method comprises the following operations:
providing electric wires integral with a support film;
cutting the electric wires into segments of electric wires of length less than the width of the first and second photovoltaic cells; and
pressing the support film against the front face of the first and second photovoltaic cells in such a way as to place in contact the electric wires with the collection fingers.

The electric wires may be cut before, during or after the step of pressing the support film against the front face of the first and second photovoltaic cells.

In an alternative embodiment, the connection elements are deposited on the front face of the first and second photovoltaic cells before the step of interconnection of the first and second photovoltaic cells.

The connection elements may extend up to the interconnection conductive track.

Preferably, the first and second photovoltaic cells are interconnected by soldering or bonding by means of an electrically conductive adhesive.

### BRIEF DESCRIPTION OF THE FIGURES

Other characteristics and advantages of the invention will become clear from the description that is given thereof below, for indicative purposes and in no way limiting, with reference to the following figures.

FIG. 1 represents schematically a technique of interconnecting photovoltaic cells according to the prior art.

FIG. 2 represents schematically another technique of interconnecting photovoltaic cells according to the prior art.

FIG. 3A shows the front face of a photovoltaic cell according to the prior art, suitable for the “shingle” interconnection technique.

FIG. 3B shows the rear face of a photovoltaic cell according to the prior art, suitable for the “shingle” interconnection technique.

FIG. 4A represents schematically and in top view a cell string according to the prior art, obtained by means of the “shingle” interconnection technique.

FIG. 4B represents schematically and in transversal section the cell string of FIG. 4A.

FIG. 5 represents a first embodiment of a photovoltaic cell according to the first aspect of the invention.

FIG. 6 represents a second embodiment of a photovoltaic cell according to the first aspect of the invention.

FIG. 7 represents a third embodiment of a photovoltaic cell according to the first aspect of the invention.

FIG. 8 represents a fourth embodiment of a photovoltaic cell according to the first aspect of the invention.

FIG. 9 represents a fifth embodiment of a photovoltaic cell according to the first aspect of the invention.

FIG. 10 represents a sixth embodiment of a photovoltaic cell according to the first aspect of the invention.

FIG. 11 represents a seventh embodiment of a photovoltaic cell according to the first aspect of the invention.

FIG. 12A represents a step of a first method for manufacturing a photovoltaic string according to the second aspect of the invention, with as example the photovoltaic cells according to FIG. 6.

FIG. 12B represents another step of the first manufacturing method.

FIG. 12C represents another step of the first manufacturing method.

FIG. 13 shows a photovoltaic string comprising several photovoltaic cells according to FIG. 7, obtained at the end of the first manufacturing method.

FIG. 14 shows a photovoltaic string comprising several photovoltaic cells according to FIG. 8, obtained at the end of the first manufacturing method.

FIG. 15A represents a step of a second method for manufacturing a photovoltaic string according to the second aspect of the invention, with as example the photovoltaic cells according to FIG. 6.

FIG. 15B shows another step of the second manufacturing method.

FIG. 15C shows another step of the second manufacturing method.

FIG. 16A represents a step of a third method for manufacturing a photovoltaic string according to the second aspect of the invention, with as example the photovoltaic cells according to FIG. 6.

FIG. 16B shows another step of the third manufacturing method.

FIG. 16C shows another step of the third manufacturing method.

FIG. 17A represents a step of a fourth method for manufacturing a photovoltaic string according to the second aspect of the invention, with as example the photovoltaic cells according to FIG. 5.

FIG. 17B shows another step of the fourth manufacturing method.

FIG. 17C shows another step of the fourth manufacturing method.

FIG. 18 represents an alternative embodiment of the step according to FIG. 16B.

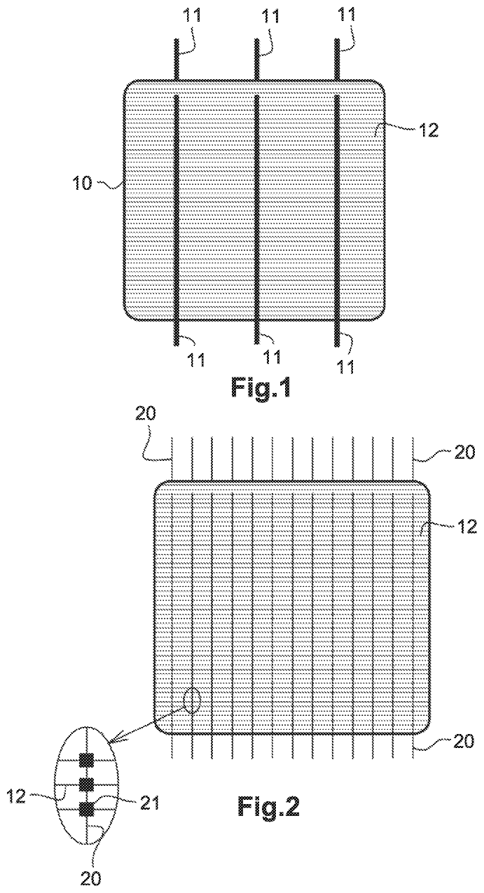

For greater clarity, identical or similar elements are marked by identical reference signs in all of the figures.

### DETAILED DESCRIPTION OF AT LEAST ONE EMBODIMENT

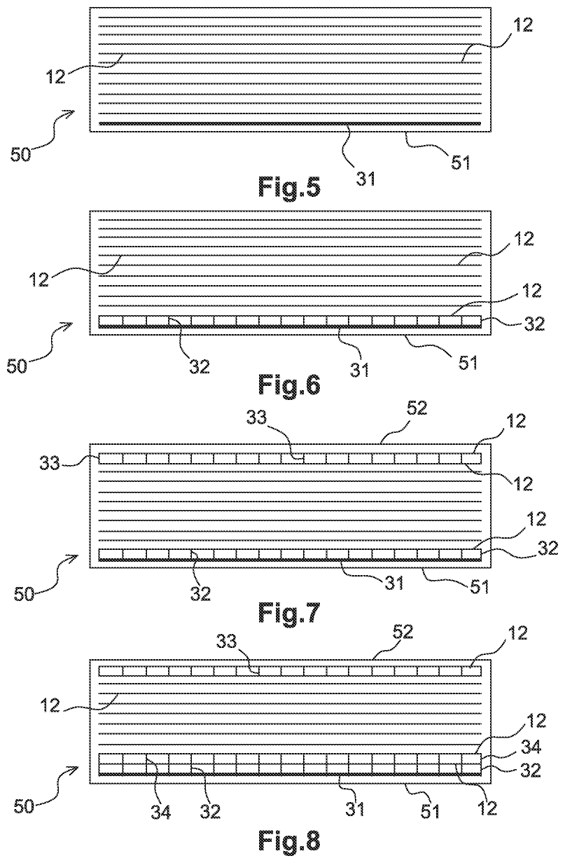

FIGS. 5 to 11 illustrate different embodiments of a photovoltaic cell 50 according to an aspect of the invention. The photovoltaic cell 50 is designed in such a way as to be able to manufacture at lower cost “shingled” cell strings. The photovoltaic cell 50 has been manufactured from a substrate made of semiconductor material, for example silicon. It may notably be a silicon homojunction (HMJ) cell or a silicon heterojunction (SHJ) cell.

The photovoltaic cell 50 comprises a front face intended to be exposed to an incident electromagnetic radiation, typically solar radiation, and a rear face opposite to the front face. The photovoltaic cell 50 may be a monofacial or bifacial cell. In a monofacial cell, only the front face captures the solar radiation. In a bifacial cell, the front and rear faces each capture a part of the solar radiation. The front face captures the incident (i.e. direct) radiation, whereas the rear face captures the scattered or reflected radiation. The front face of a bifacial cell is that making it possible to obtain the maximum of electric current when it is turned towards the incident radiation. FIGS. 5 to 11 show the front face of the photovoltaic cell 50.

The front and rear faces (also called main faces) of the photovoltaic cell 50 are advantageously parallel with each other and of same surface area. They preferably have a rectangular shape. For example, the large side of the photovoltaic cell 50 measures 156 mm whereas the small side measures 31.2 mm or 26 mm. The photovoltaic cell 50 is preferably obtained by cutting up a full size photovoltaic cell, having a standard format (for example 156 mm×156 mm). The photovoltaic cell 50 then constitutes a piece of the full size photovoltaic cell called “tile”.

The full size photovoltaic cell is advantageously cut into several tiles 50 of same surface area. Thus, the tiles will substantially produce the same electric current and a string formed of these tiles will not see its current limited by a smaller tile. As an example, each tile 50 represents a fifth or a sixth of the full size photovoltaic cell.

More generally, the front and rear faces of the photovoltaic cell 50 may have a length (large side of the rectangle) to width (small side of the rectangle) ratio comprised between 2 and 10, preferably between 4 and 6. This length to width ratio is advantageously equal to the natural integer comprised between 2 and 10, preferably between 4 and 6.

The cutting of the tiles 50 may be carried out in different ways, for example by sawing, by forming a groove with a laser then by cleaving the cell, or by a TLS (thermal laser separation) technique, which is based on a laser initiated thermal separation.

In a manner common to all the embodiments, the front face of the photovoltaic cell 50 has a plurality of collection fingers 12 and at least one interconnection conductive track 31. The collection fingers 12 and the interconnection conductive track 31 are metallisations. These metallisations are advantageously formed in a single and same step, for example by screen printing of a silver containing paste.

The collection fingers 12 are electrodes of elongated shape and parallel with each other, intended to collect the charge carriers photogenerated within the cell while allowing the quasi-totality of the incident radiation to reach the substrate. They are preferably spread out over the entire surface area of the front face. Their width is less than 100 μm, preferably less than 60 μm.

The interconnection conductive track 31, of width greater than the width of the collection fingers 12, serves to interconnect the photovoltaic cell 50 to another photovoltaic cell of the same type, to form a photovoltaic string (or daisy chain). The interconnection conductive track 31 extends parallel to a first edge 51 of the photovoltaic cell 50, preferably the large side of the cell. The distance that separates the interconnection conductive track 31 and the first edge 51 is less than 2 mm, preferably less than 1 mm. The length of the interconnection conductive track 31 (measured parallel to the first edge 51) is preferably greater than 99% of the length of the first edge 51.

The width of the interconnection conductive track 31 (measured perpendicularly to the first edge 51) is advantageously comprised between 70 μm and 700 μm. High performance electrical and mechanical connections may thus be obtained between two photovoltaic cells 50 of a same string.

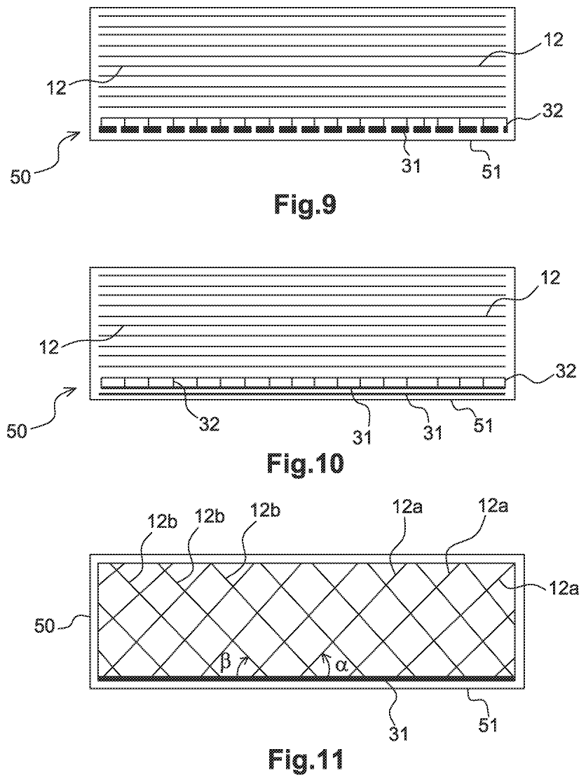

The interconnection conductive track 31 may be continuous, such as illustrated by FIGS. 5-8 and 11, or discontinuous as in FIG. 9. The front face of the photovoltaic cell 50 may also comprise more than one interconnection conductive track 31. Thus, in the embodiment of FIG. 10, the front face of the photovoltaic cell comprises two parallel interconnection conductive tracks 31.

The collection fingers 12 of the photovoltaic cell 50 are oriented with respect to the interconnection conductive track 31 by an angle comprised between −65° and 658. The smallest angle between the interconnection conductive track 31 and the collection fingers 12 is considered here. This angle is comprised between 0 and 65° in absolute value. In the embodiments illustrated by FIGS. 5 to 10, the collection fingers 12 are oriented parallel to the interconnection conductive track 31. In other words, the angle between the collection fingers 12 and the interconnection conductive track 31 is zero. In the embodiment of FIG. 11, the front face has a plurality of first collection fingers 12a oriented by a positive angle α less than 65° with respect to the interconnection conductive track 31 and a plurality of second collection fingers 12b oriented by a negative angle β greater than −65° with respect to the interconnection conductive track 31. For example, the first collection fingers 12a are oriented by an angle α equal to 45° and the second collection fingers 12b are oriented by an angle β equal to −45°.

Thus, unlike busbars employed in photovoltaic cells of the prior art, the interconnection conductive track 31 does not necessarily connect the collection fingers 12 together.

In the embodiment of FIG. 6, the front face of the photovoltaic cell 50 comprises, in addition to the collection fingers 12 and the interconnection conductive track 31, a plurality of first connecting conductors 32. The first connecting conductors 32 electrically connect the interconnection conductive track 31 to the collection finger 12 the closest to the interconnection conductive track 31.

The embodiment of FIG. 7 differs from that of FIG. 6 in that the front face of the photovoltaic cell 50 further comprises a plurality of second connecting conductors 33 electrically connecting together the two collection fingers 12 the furthest away from the interconnection conductive track 31. Consequently, the second connecting conductors 33 are close to a second edge 52 of the photovoltaic cell 50 situated opposite to the first edge 51.

In the embodiment of FIG. 8, the front face of the photovoltaic cell 50 further comprises a plurality of third connecting conductors 34 electrically connecting together the two collection fingers 12 the closest to the interconnection conductive track 31. The third connecting conductors 34 may complement the first and second connecting conductors 32-33 (cf. FIG. 8) or complement the first connecting conductors 32 uniquely.

The first, second and third connecting conductors 32, 33, 34 may be oriented perpendicularly to the interconnection conductive track 31 and to the collection fingers 12. They could thus also be qualified as first, second and third transversal conductors. They are advantageously formed at the same time as the collection fingers 12 and the interconnection conductive track 31. Their width is for example equal to that of the collection fingers 12 or comprised between 1 and 3 times the width of the collection fingers 12.

In an embodiment, the first, second and third connecting conductors 32, 33, 34 are inclined with respect to the interconnection conductive track 31 and to the collection fingers 12 by an angle comprised in absolute value between 40° and 70° (for example 60°) or between 110° and 150° (for example 120°). Such an inclination is preferable when so-called “0°” or “knotless” screen printing screens are used to facilitate the printing of the collection fingers (because these screens do not make it possible to print correctly narrow conductors oriented perpendicularly to the collection fingers).

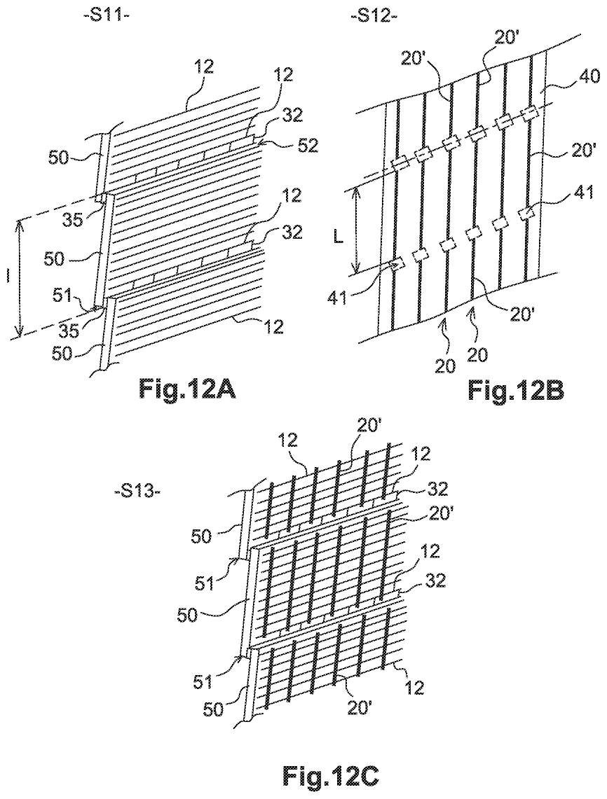

The utility of the first, second and third connecting conductors 32, 33, 34 will be described hereafter in relation with FIGS. 12 to 14.

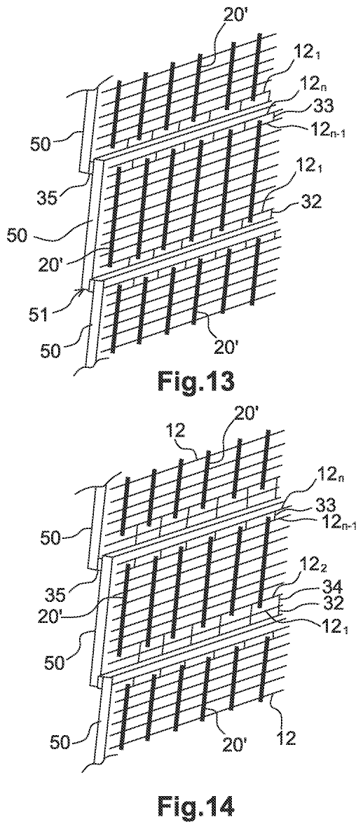

The photovoltaic cell 50 may also comprise connection elements 20, 20′ or 22 arranged on the front face of the photovoltaic cell, as illustrated in FIGS. 12C, 13, 14, 15C, 16B, 17B and 18. The connection elements 20, 20′, 22, for example in the form of electric wires or ribbons, interconnect a part at least of the collection fingers 12 of the photovoltaic cell 50. In FIGS. 13 and 14, the connection elements 20′ interconnect a part only of the collection fingers 12. In FIGS. 12C, 15C, 16B, 17B and 18, the connection elements 20, 20′, 22 interconnect all of the collection fingers 12.

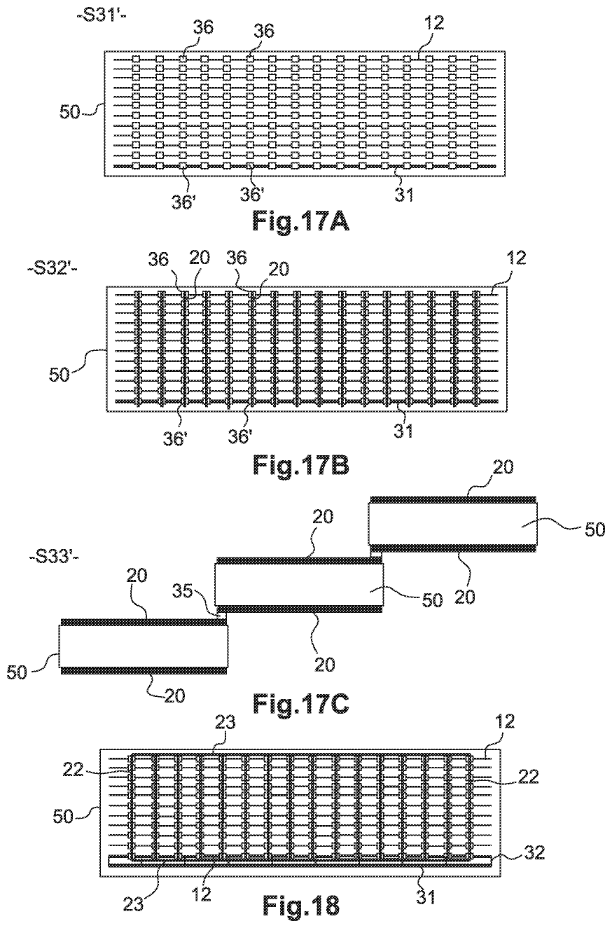

At least one of the collection fingers 12 interconnected by the connection elements 20, 20′, 22 is electrically connected to the interconnection conductive track 31. Said at least one collection finger may be connected to the interconnection conductive track 31:
directly (case of a sufficiently large angle so that the collection fingers intersect the interconnection conductive track 31; cf. FIG. 11); or
through connecting conductors 32, 34 (when the angle is sufficiently small so that none of the collection fingers 12 intersects the interconnection conductive track 31); or
through connection elements 20 in the form of wires or ribbons, when these extend up to the interconnection conductive track 31 (cf. FIGS. 17B-17C).

The rear face of the photovoltaic cell 50 may have a configuration similar to that of the front face, that is to say collection fingers, at least one interconnection conductive track and additional connection elements (in the form of wires or ribbons) interconnecting a part at least of the collection fingers of the rear face (case of a bifacial cell). The rear face may alternatively have a conventional configuration of electrodes (case of a bifacial cell), for example by screen printing the rear face with a high amount of silver, or be completely metallised and only comprise one (or several) interconnection conductive tracks (case of a monofacial cell). On the rear face, the interconnection conductive track extends along the second edge 52 of the photovoltaic cell 50. Thus, the layout of the metallisations and the connection elements described previously may only concern the front face of the photovoltaic cell 50, whatever the type of photovoltaic cell, bifacial or monofacial.

Another aspect of the invention, relating to a method for manufacturing a photovoltaic string (or method for interconnecting photovoltaic cells) will now be described with reference to FIGS. 12 to 18. The photovoltaic string comprises at least two photovoltaic cells 50 electrically connected in series. Naturally, the number of photovoltaic cells 50 in the photovoltaic string may be greater than 2. It is typically comprised between 50 and 80 (according to the format of the cells/tiles and that of the module).

FIGS. 12A-12C illustrate a first embodiment of the method for manufacturing a photovoltaic string. The different steps of the method will be described in detail with the aid of these figures taking as example the photovoltaic cells 50 of FIG. 6. In order not to pointlessly complicate FIGS. 12A and 12C, only three photovoltaic cells 50 have been represented.

With reference to FIG. 12A, the method comprises a step S11 consisting in connecting, mechanically and electrically, the photovoltaic cells 50 to one another by overlapping them, front face against rear face. A “shingled” cell string is thus formed. A portion of the front face of each cell, except for the final cell of the string, is overlapped by the following cell in the string. The interconnection conductive track 31 of the cell is situated in this portion called “overlap zone”. It is interconnected with the interconnection conductive track situated on the rear face of the following cell, for example by means of an electrically conductive adhesive (ECA) 35. A soldering technique may alternatively be used to interconnect the interconnection conductive tracks 31. The use of an electrically conductive adhesive 35 may make it possible to obtain a more reliable interconnection, because the adhesive is more ductile than a solder.

The photovoltaic cells 50 of the string are preferably aligned in a direction perpendicular to the first edges 51 of the photovoltaic cells 50. The overlap zone is then a strip of constant width which extends over the entire length of the first edge 51.

At this stage, the collection of the photogenerated charge carriers is very inefficient because, on the front face of each cell, all the collection fingers 12 are not connected to the interconnection conductive track 31 (and thus to the other cells of the string). The performances of the “shingled” cell string, in terms of current and efficiency notably, are thus very low. The other steps of the method aim to interconnect all of the collection fingers 12 to the interconnection conductive track 31. To do so, connection elements are going to be used.

FIG. 12B represents step S12 of preparation of these connection elements, before their transfer onto the front face of the photovoltaic cells 50.

In this first embodiment, the connection elements are formed of electric wires 20 integral with a support film 40, in the manner of a sheet of wires and in accordance with “SmartWire” technology. The support film 40 has an adhesive character when it is heated to a temperature comprised between 100° C. and 120° C. This adhesive character makes it possible to maintain the electric wires 20 on the support film 40 and the bonding of the support film on the photovoltaic cells 50. The support film 40 is for example formed of two superimposed layers, a layer of polyethylene terephthalate (PET) and a layer of low density polyethylene (LD-PE), or a single layer of polyolefin. The polyolefin support film has a better resistance to ultraviolet (UV) rays than the PET/LD-PE bilayer support film. The support film 40 has dimensions substantially identical to those of the “shingled” cell string, obtained at the end of step S11 (cf. FIG. 12A).

The electric wires 20 maintained by the support film 40 are preferably parallel with each other. Their number is for example comprised between 10 and 36 (for photovoltaic cells 50 of length comprised between 156 mm and 162 mm) and their diameter is advantageously comprised between 100 μm and 200 μm. They comprise a metal core, for example copper, and a covering formed of a metal alloy having a melting temperature less than 150° C. The metal alloy is for example composed of indium and tin (InSn) or tin, bismuth and silver (SnBiAg).

The electric wires 20, initially continuous, are cut after their bonding on the support film 40 in order to form groups of segments of wires 20′. The number of groups of segments of wires 20′ is identical to the number of photovoltaic cells 50 in the string and, in each group, the segments of wires 20′ are advantageously aligned. The segments of wires 20′ have a length L slightly less than the width l of a photovoltaic cell 50. To carry out this cutting, portions of wire of length greater than or equal to the width of the overlap zones are advantageously removed in so-called cutting zones 41. For example, the overlap zones of the photovoltaic cells 50 have a width of 1 mm whereas the removed wire portions have a length of 2 mm. The cutting zones 41 are for example obtained by punching of the electric wires 20 and the support film 40.

The provision of electric wires 20 and the support film 40, then the cutting of the electric wires 20 into segments of wires 20′ being operations independent of the formation of the “shingled” cell string, step S12 of FIG. 12B may be carried out before, after or in parallel with step S11 of FIG. 12A.

Step S13 of FIG. 12C consists in pressing the support film 40 against the front face of the photovoltaic cells 50 in such a way as to bring each group of segments of wires 20′ directly into contact with the collection fingers 12 of an associated cell. Preferably, the arrangement of the electric wires 20 on the support film 40 is such that, when the support film 40 is applied on the string of cells, the segments of wires 20′ are situated oriented perpendicularly to the first edges 51 of the photovoltaic cells 50, in other words in the direction of “stringing” of the photovoltaic cells 50. The segments of wires 20′ of each group have in FIG. 12C a sufficient length to contact all of the collection fingers 12 of the associated cell.

Before pressing the support film 40, the cutting zones 41 are aligned on the overlap zones of the photovoltaic cells 50. They next cover a side wall of the photovoltaic cells 50. Thanks to the cutting zones 41, the front faces of the photovoltaic cells 50 are not short-circuited between each other.

Since the support film 40 is flexible, said film may be pressed against the photovoltaic cells 50 by laminating using a roller. The roller is advantageously heated to a temperature comprised between 100° C. and 120° C. to improve the adhesion of the support film 40 on the cells.

At the end of step S13, the electric contact between the segments of wires 20′ and the collection fingers 12 is not yet established. This electric contact takes place during a later step by melting of the covering of the wires, and preferably, during the step of lamination of the photovoltaic module (accomplished at a temperature of 145° C.-165° C.).

This embodiment of the manufacturing method, when it uses the photovoltaic cells 50 of FIG. 6, requires a high alignment precision in order that the segments of wires 20′ come into contact with the collection finger 12 situated the nearest to the interconnection conductive track 31 (and outside of the overlap zone). Since this collection finger 12 is electrically connected to the interconnection conductive track 31 (situated in the overlap zone) by the first connecting conductors 32, electrical continuity is ensured between the interconnected collection fingers 12 and the interconnection conductive track 31.

Thus, thanks to the first connecting conductors 32, the electric wires do not need to extend up to the overlap zone to be in contact with the interconnection conductive track 31. The thickness of electrically conductive adhesive 35 required to interconnect the photovoltaic cells 50 may thus be minimised.

A second sheet of wires, identical to that described in relation with FIG. 12B, may be provided and applied against the rear faces of the photovoltaic cells 50. This second sheet of wires is useful uniquely in the case of bifacial cells provided with collection fingers 12 on the rear face. In the case of monofacial cells, the collection of the charge carriers on the rear face and their conveyance to the interconnection conductive track may be ensured by an electrically conductive layer (for example made of aluminium) covering the entire rear face.

FIG. 13 shows a photovoltaic string obtained when the manufacturing method according to the first embodiment (steps S11-S13, cf. FIGS. 12A-12B) is accomplished with the photovoltaic cells 50 of FIG. 7 (rather than with those of FIG. 6). In this second case, the alignment constraint is lower because the segments of wires 20′ may not contact the collection finger 12n the furthest away from the interconnection conductive track 31, qualified as “final” collection finger going from the first edge 51. Indeed, the second connecting conductors 33 ensure the electrical continuity between this final collection finger 12n and the penultimate collection finger 12ₙ₋₁. In other words, the interconnection of the collection fingers 12 by the segments of wires 20′ may begin at the first collection finger 121 (the closest to the interconnection conductive track 31 and situated outside of the overlap zone) and stop at the penultimate collection finger 12ₙ₋₁.

FIG. 14 shows a photovoltaic string obtained when the manufacturing method according to the first embodiment is accomplished with the photovoltaic cells 50 of FIG. 8 (rather than with those of FIG. 6 or FIG. 7). In this third case, the alignment constraint is even lower because the first collection finger 121, like the final collection finger 12n, may not be interconnected by the segments of wires 20′. The first collection finger 121 is in fact electrically connected to the second collection finger 122 (interconnected with the others thanks to the segments of wires) by the third connecting conductors 34, whereas the final collection finger 12n is electrically connected to the penultimate collection finger 12ₙ₋₁ by the second connecting conductors 33.

Thus, the second and third connecting conductors 33-34 facilitate step S13 of transfer of the sheet of electric wires onto the photovoltaic cells 50.

The first embodiment of the manufacturing method (steps S11-S13, cf. FIGS. 12A-12B) is compatible with other embodiments of the photovoltaic cell 50 than those of FIGS. 5 to 7, notably those of FIGS. 9 to 11.

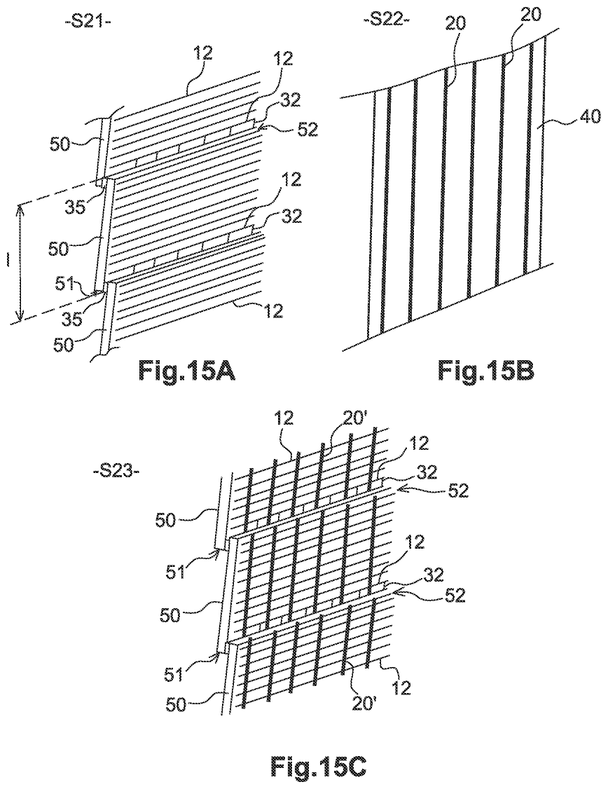

FIGS. 15A to 15C illustrate a second embodiment of the method for manufacturing a photovoltaic string.

With reference to FIG. 15A, the photovoltaic cells 50 are arranged in a “shingled” (i.e. cascaded) cell string in the same manner as that described in relation with FIG. 12A.

FIG. 15B represents a step S22 of preparation of a sheet of wires intended to be transferred onto the string of photovoltaic cells 50. This sheet of wires, of the same type as that provided at the start of step S12, comprises a plurality of continuous electric wires 20 and a support film 40 on which are bonded the electric wires 20. However, unlike the first embodiment, no cutting of the electric wires 20 is carried out at this step.

At step S23 of FIG. 15C, the support film 40 is next pressed against the front face of the photovoltaic cells 50 in such a way as to place in contact the electric wires 20 with the collection fingers 12. During this same step, the electric wires 20 are pressed against protruding ridges delimiting the second edge 52 of the photovoltaic cells 50. The electric wires 20 are then broken at the level of these protruding ridges, thus obtaining the different groups of segments of wires 20′. Such protruding ridges may be obtained during the sawing or the cleavage of the full size photovoltaic cell (the cleavage being advantageously initiated by laser or the formation of a groove).

The support film 40 may be pressed against the photovoltaic cells 50, and the cut electric wires 20, by passing a roller on the “shingled” cell string. The diameter of the electric wires 20 is advantageously less than or equal to 150 μm, preferably comprised between 50 μm and 100 μm, in order that they can be cut easily without exerting a too high mechanical stress on the “shingled” cell string.

The cutting of the electric wires 20 may also be accomplished after the pressing of the support film 40 on the front face of the photovoltaic cells 50.

Thus, in this second embodiment, the electric wires 20 integral with the support film 40 (“SmartWire” type) are cut into segments of wires 20′ during or after their transfer onto the front face of the photovoltaic cells 50, whereas in the first embodiment, they are cut into segments of wires 20′ before their transfer (cf. step S12 of FIG. 12B).

Following the example of the first embodiment, the second embodiment is compatible with all the embodiments of the photovoltaic cell 50, with the exception of that of FIG. 5.

The manufacturing method according to the second embodiment does away with the constraint of alignment of the cutting zones on the overlap zones and of a cutting operation in its own right. It is thus faster and simpler to implement.

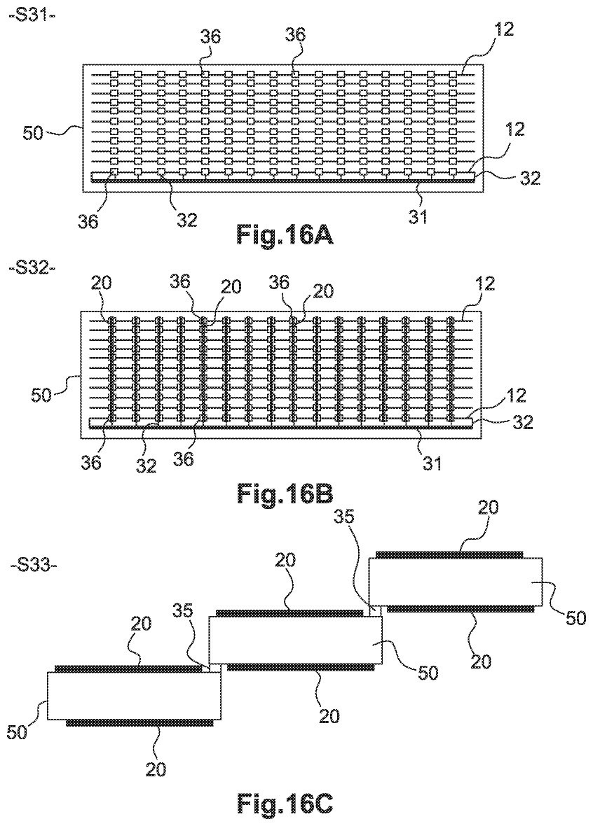

FIGS. 16A to 16C illustrate a third embodiment of the method for manufacturing a photovoltaic string. This third embodiment differs from the first and second embodiments in that a part at least of the collection fingers 12 are interconnected by electric wires before the cells 50 are “shingle” interconnected. It will be described in detail taking as example the photovoltaic cells of the type represented in FIG. 6.

FIG. 16A represents a step S31 of deposition of a solder paste (or brazing paste) on the collection fingers 12 of each photovoltaic cell 50 to interconnect. The solder paste is deposited, for example by screen printing, in such a way as to form a plurality of solder pads 36 aligned on the collection fingers 12. These solder pads 36 are intended to receive the electric wires. They form, perpendicularly to the collection fingers 12, a plurality of discontinuous connection tracks (in a similar manner to the discontinuous “busbars” formed of metallisation pads). The solder paste is for example composed of beads made of SnPb/SnPbAg alloy (melting temperature greater than 170° C.) or made of SnBiAg alloy (lower melting temperature).

Next, at step S32 of FIG. 16B, electric wires 20 are soldered to the collection fingers 12 of each photovoltaic cell 50 by means of solder pads 36. The electric wires 20 are firstly placed in contact with the solder pads 36 then the solder paste is melted by heating, for example at a temperature of around 200° C. (SnPb/SnPbAg type brazing paste) or around 150° C. (SnBiAg type brazing paste). The solder pads 36 suffice to form a durable and not very resistive electrical connection between the electric wires 20 and the collection fingers 12. Thus, in this third embodiment, the electric wires 20 are not necessarily covered with a low temperature fusible alloy. Using non-covered wires (i.e. formed of a single metal), for example uniquely copper, reduces the cost of manufacturing the photovoltaic string.

In FIG. 16B, the electric wires 20 have a sufficient length to interconnect all the collection fingers 12 of the cell. The (interconnected) collection fingers 12 are furthermore electrically connected to the interconnection conductive track 31 by means of the first connecting conductors 32.

Finally, several photovoltaic cells 50 each provided with electric wires 20 are “shingle” interconnected during a step S33 illustrated by FIG. 16C. Since in this example the electric wires 20 do not extend up to the interconnection conductive track 31, and thus into the overlap zone, the amount of electrically conductive adhesive 35 necessary to interconnect two photovoltaic cells 50 may be minimised. The electric wires have in this example a diameter less than or equal to 150 μm, preferably comprised between 75 μm and 125 μm.

As represented in FIG. 16C, solder pads may also be formed on the collection fingers present on the rear face of the photovoltaic cells 50 in order to connect thereto electric wires 20 (case of bifacial cells).

After the step S31 of deposition of the solder paste and before the step S32 of soldering of the electric wires 20 on the collection fingers 12, the manufacturing method may comprise a step consisting in pre-melting the solder pads 36. This pre-melting step tends to uniformise the volume of solder attached to the collection fingers 12. In other words, the solder paste is spread out more uniformly on the collection fingers 12. A constant solder volume makes it possible to homogenise the quality of the interconnections.

Conversely, when a solder pad 36 is melted for the first time in the presence of an electric wire 20, the solder paste spreads out between the collection finger 12 and the electric wire 20. Since this spreading is variable, volumes of solder attached to the collection fingers 12 which vary from one solder pad to the other are obtained.

The steps of deposition of solder paste and of pre-melting of the solder pads may be accomplished on each of the photovoltaic cells 50, as is represented by FIG. 16A, or on full size photovoltaic cells before their cutting.

On melting, the solder paste can overflow from the collection fingers 12 onto the substrate of the photovoltaic cells. The overflow zone, that is to say the zone of the substrate covered by the molten solder paste, is variable as a function of the solder pads (notably due to differences in volume of paste deposited, differences in misalignment with respect to the collection finger during the deposition of the solder paste and differences in wettability between the collection fingers). The overflow zones of the solder paste thus do not cause the same shading from one cell to the other, which results in different electric currents between the cells. Thus, in the case of pre-melting of the solder pads 36, the manufacturing method advantageously comprises a step of sorting of the photovoltaic cells on the basis of I-V characteristics. The photovoltaic cells may thus be grouped together by current values, with the aim of maximising the current of the photovoltaic strings. The I-V sorting is preferably carried out after the cutting of the full size photovoltaic cells, in other words with the photovoltaic cells 50, because the overflow of the solder paste has a more important impact on cells of small size.

FIGS. 17A to 17C represent an alternative embodiment of the manufacturing method described in relation with FIGS. 16A-16C. In this alternative embodiment, the photovoltaic cells 50 according to the embodiment of FIG. 5 may be used.

The solder paste is deposited, at step S31′ of FIG. 17A, in such a way as to form, in addition to solder pads 36 aligned on the collection fingers 12, additional solder pads 36′ aligned on the interconnection conductive track 31. The additional solder pads 36′ are situated in the extension of the discontinuous connection tracks formed by the solder pads 36.

It is then possible to extend the electric wires 20 up to the interconnection conductive track 31, so that they are soldered therewith during a step S32′ (cf. FIG. 17B).

Finally, the photovoltaic cells 50 are interconnected in the form of a “shingled” cell string, by means of an electrically conductive adhesive 35 arranged in the overlap zones of the cells.

The electric wires 20 used in this alternative embodiment of the manufacturing method are preferably of smaller diameter than those used previously during steps S31-S33, advantageously of diameter less than 100 μm. This makes it possible to limit the amount of electrically conductive adhesive used, despite the extra thickness linked to the electric wires 20 situated in the overlap zones.

In the third embodiment of the manufacturing method (FIGS. 16A-16C) as in the alternative embodiment described with reference to FIGS. 17A-17C, electric ribbons may be used as connection elements instead of electric wires 20. However, if they are less advantageous in terms of shading (and thus of current generated) on account of their rectangular section (electric wires, of circular section, have an effective shading on the photovoltaic cell equal to 70% only of their diameter, compared to 100% of the width of the ribbons).

Whereas wires and ribbons constitute in conventional cell strings (apart from “shingled” cell strings which are exempt from such wires or ribbons) so-called “interconnection” elements serving to interconnect the cells, they are used here to connect the collection fingers together and potentially to the interconnection conductive track actually within each cell.

FIG. 18 furthermore shows that a metal grid may be used instead of electric wires 20 during step S32 or S32′. This metal grid comprises for example a plurality of first wires 22 parallel with each other, intended to be soldered to the collection fingers 12 through solder pads 36, and a plurality of second wires 23 connecting the first wires 22 together at their ends. The metal grid, formed for example of silver or copper, advantageously has a thickness comprised between 70 μm and 100 μm when it does not reach the coverage zone (cf. FIG. 18) and a thickness comprised between 35 μm and 70 μm when it reaches the coverage zone (not represented).

In another embodiment of the manufacturing method, not represented by the figures, photovoltaic cells 50 provided with solder pads 36 (cf. FIG. 16A or 17A) are firstly interconnected to form a “shingled” cell string, then continuous electric wires (diameter <100 μm, without support film, with or without covering) are soldered to the collection fingers of the photovoltaic cells 50 by melting of the solder pads 36 (pre-melted or not). After their soldering, the electric wires are cut by pressing them against the projecting ridges of the photovoltaic cells 50, for example using a roller.

Generally, the method for manufacturing photovoltaic strings according to an aspect of the invention comprises the following steps:
providing first and second photovoltaic cells 50 according to any one of the embodiments represented by FIGS. 5 to 11;
interconnecting (steps S12-S13 of FIGS. 12B-12C; steps S22-S23 of FIGS. 15B-15C; steps S31-S32 of FIGS. 16A-16B; steps S31′-S32′ of FIGS. 17A-17B) in each of the photovoltaic cells 50 a part at least of the collection fingers 12 by connection elements 20, 20′, 22 in the form of wires or ribbons deposited on the front face;
interconnecting (step S11 of FIG. 12A, step S21 of FIG. 15A, step S33 of FIG. 16C, step S33′ of FIG. 17C) the photovoltaic cells 50, by overlapping with the rear face of the second photovoltaic cell a portion of the front face of the first photovoltaic cell wherein is situated the interconnection conductive track 31.

In the first and second embodiments of the method (FIGS. 12A-12C & 15A-15C), the connection elements 20, 20′ are deposited on the front face of the photovoltaic cells 50 after the step of interconnection of the photovoltaic cells 50. In the third embodiment of the method and its alternative (FIGS. 16A-16C & 17A-17C), the connection elements 20 are deposited on the front face of the photovoltaic cells 50 before the step of interconnection of the photovoltaic cells 50. In this case, it may also be considered that the interconnection of the collection fingers by the connection elements in each photovoltaic cell 50 forms part of the method for manufacturing the photovoltaic cell.

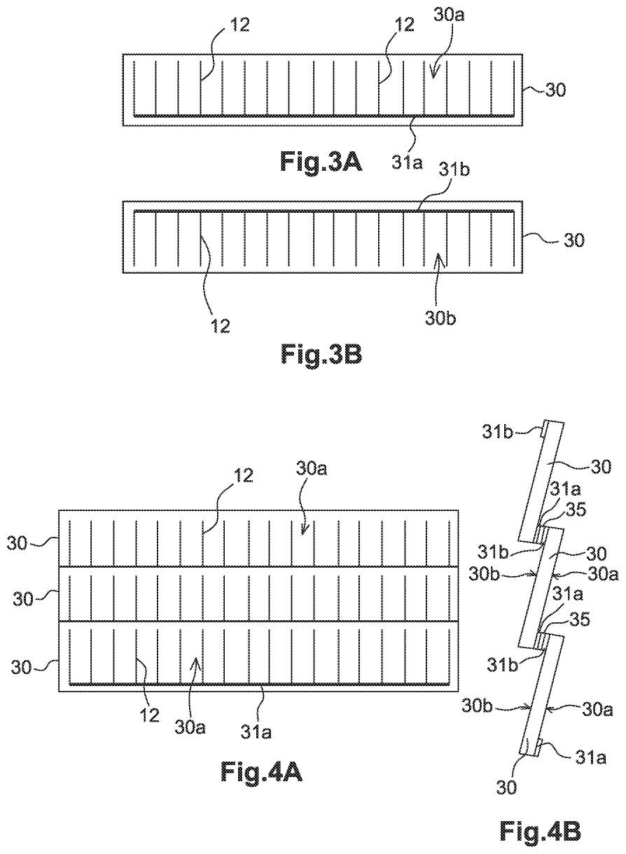

In the photovoltaic strings described above and represented by FIGS. 12C, 13-14, 15C, 16C and 17C, the electric current circulates within each photovoltaic cell 50 mainly through the connection elements (for example of wire type) which are much less resistive than the collection fingers (0.02Ω for 1 cm of copper wire of 100 μm diameter, compared to 0.4Ω to 8Ω for 1 cm of collection finger depending on the geometry). Indeed, once extracted from the substrate, the charge carriers only transit through the collection fingers over a small distance, to reach the closest connection element. This short travel distance in the collection fingers allows the formation of more resistive collection fingers (preferably 2Ω to 7Ω), that is to say of smaller section and/or formed with a less conductive paste (and thus less rich in silver), without this deteriorating the series resistance of the cell once interconnected. For example, the section of the collection fingers in the photovoltaic cell 50 may be equal to 45 μm×6 μm, compared to 70 μm×15 μm in the “shingled” photovoltaic cell 30 of the prior art (cf. FIG. 3). The total consumption of silver per bifacial photovoltaic cell 50 may be less than 100 mg, compared to more than 300 mg for the photovoltaic cell 30 of the prior art. The photovoltaic cell 50 is consequently cheaper to manufacture. Furthermore, the collection fingers being less thick, they can be printed in a single pass (instead of two passes normally), which also contributes to decreasing the cost of a cell.

The resistive losses linked to transport in the collection fingers and the connection elements are less important in the photovoltaic string of the invention than in the “shingled” cell string of the prior art (exempt of connection elements). The fill factor (FF) of a module manufactured from photovoltaic strings according to the invention will thus be better than that of a “shingled” module according to the prior art.

These benefits are particularly interesting for the formation of silicon heterojunction (SHJ) strings of cells, because this type of photovoltaic cell is penalised by a greater consumption of silver than that of homojunction cells (HMJ). Indeed, the screen printing pastes compatible with the “low temperature” manufacturing method of heterojunction cells are (for a same amount of silver) less electrically conductive (resistivity of 2-2.5 μΩ·cm for high temperature pastes and 4-7 μΩ·cm for high temperature pastes).

The collection fingers of the photovoltaic cell 50 having a reduced section, they bring about less shading on the front face of the cell. The additional shading caused by the electric wires (absent from the “shingled” photovoltaic cell 30 of the prior art) is low, given the small diameter of the wires (<100 μm) and their reduced effective shading level (70% of the diameter). This additional shading is less than the decrease in shading linked to the smallest section of the collection fingers. Thus, by orienting the collection fingers in such a way as to be able to interconnect them by wires, overall the shading on the front face of the cell is decreased, which results in a gain in current.

Since the resistance linked to the transport of the current decreases, it is advantageous to form strings with tiles of greater surface area (and thus of greater current), for example thirds or quarters of a full size photovoltaic cell rather than fifths or sixths of a full size photovoltaic cell. Thus, losses by recombination of electron-hole pairs at the level of the cut (and not passivated) edges of the tiles are decreased.

Finally, the photovoltaic strings of the invention have the advantages of the conventional “shingle” interconnection technique, in terms of active surface and module efficiency notably.

1. A photovoltaic cell comprising a front face intended to be exposed to an incident radiation and a rear face opposite to the front face, the front face having:
a plurality of electrodes parallel with each other and forming collection fingers;
an interconnection conductive track of width greater than a width of the collection fingers, extending parallel to an edge of the photovoltaic cell at less than 2 mm from said edge of the photovoltaic cell, the collection fingers being oriented with respect to the interconnection conductive track by an angle (α, β) comprised between −65° and 65°;
wherein a part at least of the collection fingers are interconnected by connection elements in the form of wires or ribbons arranged on the front face.

2. The photovoltaic cell according to claim 1, wherein the width of the interconnection conductive track is comprised between 70 μm and 700 μm.

3. The photovoltaic cell according to claim 1, wherein the connection elements are oriented perpendicularly to the interconnection conductive track.

4. The photovoltaic cell according to claim 1, wherein the collection fingers are oriented parallel to the interconnection conductive track.

5. The photovoltaic cell according to claim 1, further comprising first connecting conductors electrically connecting the interconnection conductive track to the collection finger the closest to the interconnection conductive track.

6. The photovoltaic cell according to claim 5, further comprising second connecting conductors electrically connecting together the two collection fingers the furthest away from the interconnection conductive track.

7. The photovoltaic cell according to claim 5, further comprising third connecting conductors electrically connecting together the two collection fingers the closest to the interconnection conductive track.

8. The photovoltaic cell according to claim 1, further comprising a plurality of first solder pads aligned on the collection fingers and forming, perpendicularly to the collection fingers, a plurality of discontinuous connection tracks.

9. The photovoltaic cell according to claim 8, wherein the connection elements are fixed to the collection fingers through discontinuous connection tracks.

10. The photovoltaic cell according to claim 9, further comprising a plurality of second solder pads aligned on the interconnection conductive track, in the extension of the discontinuous connection tracks, the connection elements being further fixed to the interconnection conductive track through second solder pads.

11. The photovoltaic cell according to claim 1, wherein at least one of the interconnected collection fingers is electrically connected to the interconnection conductive track.

12. The photovoltaic cell according to claim 1, wherein the rear face has:
a plurality of electrodes parallel with each other forming collection fingers;
an interconnection conductive track of width greater than a width of the collection fingers of the rear face, extending parallel to an edge of the photovoltaic cell at less than 2 mm from said edge of the photovoltaic cell, the collection fingers of the rear face being oriented with respect to the interconnection conductive track of the rear face by an angle comprised between −65° and 65°;
and wherein a part at least of the collection fingers of the rear face are interconnected by additional connection elements in the form of wires or ribbons arranged on the rear face.

13. The photovoltaic string comprising first and second photovoltaic cells according to claim 1, the second photovoltaic cell being interconnected with the first photovoltaic cell by overlapping with the rear face of the second photovoltaic cell a portion of the front face of the first cell wherein is situated the interconnection conductive track.

14. The photovoltaic string according to claim 13, wherein the connection elements are electric wires and wherein the electric wires are integral with a support film arranged against the front faces of the first and second photovoltaic cells.

15. The photovoltaic string according to claim 13, wherein the connection elements extend up to the interconnection conductive track.

16. A method for manufacturing a photovoltaic cell comprising:
forming on a face of a substrate a plurality of electrodes parallel with each other forming collection fingers, and an interconnection conductive track of width greater than a width of the collection fingers, the interconnection conductive track extending parallel to an edge of the substrate at less than 2 mm from said edge of the substrate and the collection fingers being oriented with respect to the interconnection conductive track by an angle comprised between −65° and 65°;
interconnecting a part at least of the collection fingers by connection elements in the form of wires or ribbons deposited on the face of the substrate.

17. A method for manufacturing a photovoltaic string comprising:
providing first and second photovoltaic cells each comprising a front face intended to be exposed to an incident radiation and a rear face opposite to the front face, the front face having:
a plurality of electrodes parallel with each other and forming collection fingers;
an interconnection conductive track of width greater than a width of the collection fingers, extending parallel to an edge of the photovoltaic cell at less than 2 mm from said edge of the photovoltaic cell, the collection fingers being oriented with respect to the interconnection conductive track by an angle comprised between −65° and 65°;
interconnecting in each of the first and second photovoltaic cells a part at least of the collection fingers by connection elements in the form of wires or ribbons deposited on the front face;
interconnecting the second photovoltaic cell with the first photovoltaic cell, by overlapping with the rear face of the second photovoltaic cell a portion of the front face of the first photovoltaic cell wherein is situated the interconnection conductive track.

18. The method according to claim 17, wherein the connection elements are deposited on the front face of the first and second photovoltaic cells after the interconnection of the first and second photovoltaic cells.

19. The method according to claim 18, comprising the following operations:
providing electric wires integral with a support film;
cutting the electric wires into segments of electric wires of length less than the width of the first and second photovoltaic cells; and
pressing the support film against the front face of the first and second photovoltaic cells in such a way as to place in contact the electric wires with the collection fingers.

20. The method according to claim 17, wherein the connection elements are deposited on the front face of the first and second photovoltaic cells before the interconnection of the first and second photovoltaic cells.

21. The method according to claim 20, wherein the connection elements extend up to the interconnection conductive track.

22. The method according to claim 17, wherein the first and second photovoltaic cells are interconnected by soldering or by bonding by means of an electrically conductive adhesive.
